(19) United States
(12) Patent Application Publication
(10) Pub. No.: US 2009/0289299 A1
(43) Pub. Date: Nov. 26, 2009

(54) HIGH DENSITY HIGH PERFORMANCE POWER TRANSISTOR LAYOUT

(76) Inventors: Li-Cheng CHEN, Kaohsiung City (TW); Feng-Yuan AN, Kaohsiung City (TW)

Correspondence Address: NORTH AMERICA INTELLECTUAL PROPERTY CORPORATION, P.O. BOX 506, MERRIFIELD, VA, 22116, US

(21) Appl. No.: 12/125,070

(22) Filed: May 22, 2008

(51) Int. Cl. H01L 29/78

(52) U.S. Cl. 257/342; 257/E29.256

(57) ABSTRACT

A power transistor comprises a gate region, a source region, and a drain region. The gate region comprises a first line portion, a second line portion, and a third line portion. The first line portion couples to the second line portion so as to form a first V-shaped structure. The second line portion couples to the third line portion so as to form a second V-shaped structure. The first line portion, the second line portion, and the third line portion form a N-shaped structure.

### BACKGROUND OF THE INVENTION

1. Field of the Invention

The present invention relates to a power transistor layout and, more particularly, to a high density high performance power transistor layout.

2. Description of the Related Art

FIG. 1 is a conventional layout showing a power transistor 10. The power transistor 10 can be applied to a power converter for power management. As to the example of FIG. 1, the power transistor 10 is implemented by a PMOS transistor. The power transistor 10 comprises a gate region 11, a source region 12, and a drain region 13. The source region 12 comprises a plurality of well pickup contacts 15a and a plurality of source contacts 15b, where the well pickup contacts 15a are located in a N-type diffusion region 14 and the source contacts 15b are located in a P-type diffusion region 16. The drain region 13 comprises a plurality of drain contacts 15c, where the drain contacts 15c are located in the P-type diffusion region 16. Such layout reveals a so-called Hive-shaped structure. The gate region 11 is bended with 45 degrees repeatedly so as to increase the effective channel width of the power transistor 10.

As shown in FIG. 1, the equivalent transistor, formed by a bended portion 11a of the gate region 11, the source region 12, and the drain region 13, has a low on-resistance of source-to-drain (Rds_on) because the corresponding source contacts 15b and drain contacts 15c are near the bended portion 11a, thereby achieving a better performance. However, the equivalent transistor, formed by a horizontal portion 11b of the gate region 11, the source region 12, and the drain region 13, has a high Rds_on because the corresponding source contacts 15b are not near the horizontal portion 11b, thereby achieving a worse performance.

### SUMMARY OF THE INVENTION

In view of the above-mentioned problem, an object of the present invention is to provide a high density high performance power transistor layout.

According to the present invention, a layout of a power transistor is provided. The power transistor comprises a gate region, a source region, and a drain region. The gate region comprises a first line portion, a second line portion, and a third line portion. The first line portion couples to the second line portion so as to form a first angle. The first line portion and the second line portion form a first V-shaped structure. The second line portion couples to the third line portion so as to form a second angle. The second line portion and the third line portion form a second V-shaped structure. The first line portion, the second line portion, and the third line portion form a N-shaped structure.

### BRIEF DESCRIPTION OF THE DRAWINGS

The above-mentioned and other objects, features, and advantages of the present invention will become apparent with reference to the following descriptions and accompanying drawings, wherein:

FIG. 1 is a conventional layout showing a power transistor;

FIG. 2 is a layout showing a power transistor according to the first embodiment of the present invention;

FIG. 3 is a layout showing a power transistor according to the second embodiment of the present invention;

### DETAILED DESCRIPTION OF THE PREFERRED EMBODIMENTS

The preferred embodiments according to the present invention will be described in detail with reference to the drawings.

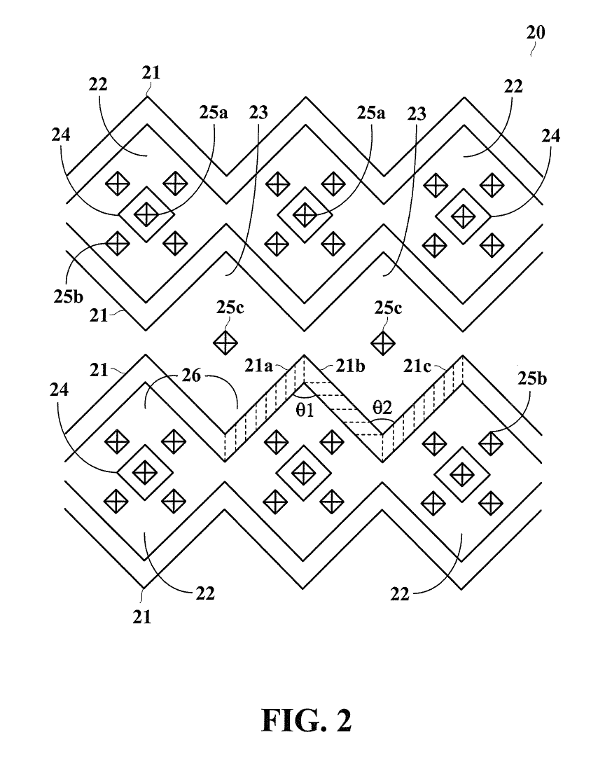

FIG. 2 is a layout showing a power transistor 20 according to the first embodiment of the present invention. The power transistor 20 can be applied to a power converter for power management. As to the example of FIG. 2, the power transistor 20 is implemented by a PMOS transistor. The power transistor 20 comprises a gate region 21, a source region 22, and a drain region 23. The source region 22 comprises a plurality of well pickup contacts 25a and a plurality of source contacts 25b, where the well pickup contacts 25a are located in a N-type diffusion region 24 and the source contacts 25b are located in a P-type diffusion region 26. The drain region 23 comprises a plurality of drain contacts 25c, where the drain contacts 25c are located in the P-type diffusion region 26.

As shown in FIG. 2, the gate region 21 adopts the bended portions entirely and thus there is no horizontal portion. That is to say, the power transistor 20, formed by the gate region 21, the source region 22, and the drain region 23, has a lower Rds_on because all the source contacts 25b and the drain contacts 25c are near the gate region 21, thereby achieving a high performance. Also, since the gate region 21 adopts the bended portions entirely, the effective channel width per unit area is larger, thereby achieving a high density as well.

To further interpret the feature of the first embodiment, FIG. 2 shows that the gate region 21 comprises a first line portion 21a, a second line portion 21b, and a third line portion 21c. The length of the first line portion 21a is equal to the length of the second line portion 21b, and the length of the second line portion 21b is equal to the length of the third line portion 21c. The first line portion 21a couples to the second line portion 21b so as to form a first angle θ1, where the first line portion 21a and the second line portion 21b form a first V-shaped structure. The second line portion 21b couples to the third line portion 21c so as to form a second angle θ2, where the second line portion 21b and the third line portion 21c form a second V-shaped structure. Moreover, the first line portion 21a, the second line portion 21b, and the third line portion 21c form a N-shaped structure. The first angle θ1 is chosen to be equal to the second angle θ2 in the first embodiment. Also, the first angle θ1 is equal to 90 degrees so as to achieve the best performance.

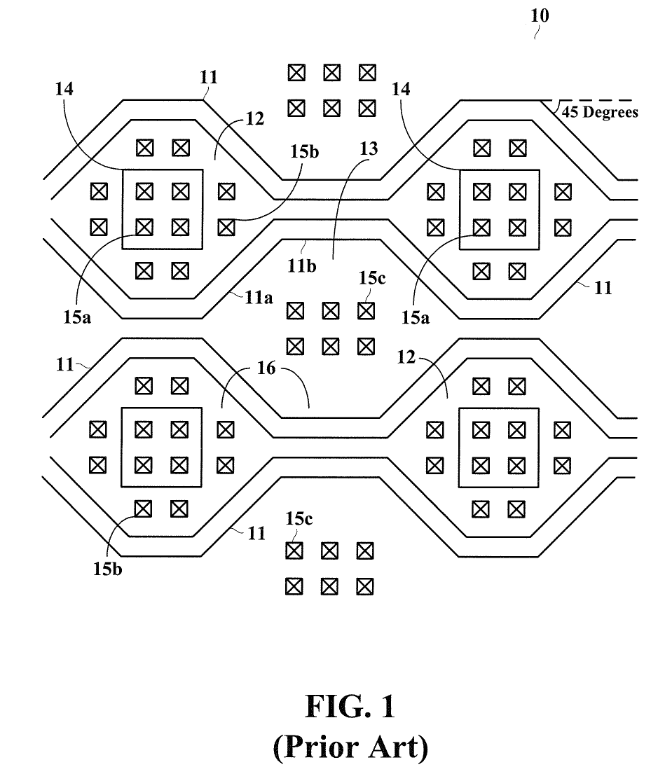

By the computation of the layout software, the effective channel width per unit area of the power transistor 20 (FIG. 2) is 1.25 times of the effective channel width per unit area of the power transistor 10 (FIG. 1). In other words, when achieving the same effective channel width, the layout area of the power transistor 20 is 80% of the layout area of the power transistor 10.

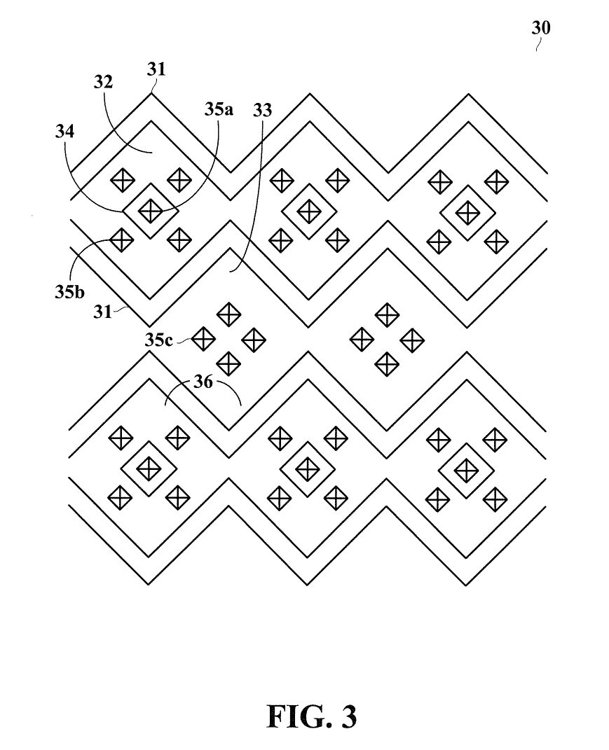

FIG. 3 is a layout showing a power transistor 30 according to the second embodiment of the present invention. As shown in FIG. 3, by increasing the number of drain contacts 35c and shortening the distances between the gate 31 and the corresponding drain contacts 35c, Rds_on can be further reduced, thereby achieving the best performance.

As mentioned before, the power transistor according to the invention can be applied to a power converter for power management. Also, the power transistor according to the invention can be applied to the other circuit which needs a large channel width.

While the invention has been described by way of examples and in terms of the preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A power transistor comprising:
a gate region having a first line portion, a second line portion, and a third line portion, wherein the first line portion couples to the second line portion so as to form a first angle, and the second line portion couples to the third line portion so as to form a second angle;
a source region; and
a drain region, wherein the first line portion and the second line portion form a first V-shaped structure, the second line portion and the third line portion form a second V-shaped structure, and the first line portion, the second line portion, and the third line portion form a N-shaped structure.

2. The power transistor according to claim 1, wherein the length of the first line portion is equal to the length of the second line portion.

3. The power transistor according to claim 2, wherein the length of the second line portion is equal to the length of the third line portion.

4. The power transistor according to claim 3, wherein the first angle is equal to the second angle.

5. The power transistor according to claim 4, wherein the first angle is equal to 90 degrees.

6. The power transistor according to claim 5, wherein the source region comprises a plurality of well pickup contacts and a plurality of source contacts.

7. The power transistor according to claim 6, wherein the well pickup contacts are located in a N-type diffusion region and the source contacts are located in a P-type diffusion region.

8. The power transistor according to claim 7, wherein the drain region comprises a plurality of drain contacts.

9. The power transistor according to claim 8, wherein the drain contacts are located in the P-type diffusion region.

10. The power transistor according to claim 9, wherein the power transistor is applied to a power converter.
